(19) United States
(12) Patent Application Publication
(10) Pub. No.: US 2005/0111601 A1
(43) Pub. Date: May 26, 2005

(54) Apparatus and method for synchronizing a circuit during reception of a modulated signal

(76) Inventor: Christian Bock, Freiburg (DE)

Correspondence Address: Patrick J. O'Shea;O'Shea, Getz & Kosakowski, P.C., Suite 912, 1500 Main Street, Springfield, MA, 01115, US

(21) Appl. No.: 10/962,192

(22) Filed: Oct. 8, 2004

(30) Foreign Application Priority Data
Oct. 8, 2003 (DE) DE 103 47 259.2

(51) Int. Cl. H03D 1/00

(52) U.S. Cl. 375/354

(57) ABSTRACT

The invention relates to a method for synchronizing a circuit (1) during reception of a modulated signal (sa, sd, A) that has been mixed in the multidimensional complex signal space, specifically, in a QAM-receiver, wherein a decision element (15, 15′, 15*) is employed to analyze the received signal within a complex coordinate space (I, Q) using control parameters (ΔR, ρ, tᵢ) so as to make a decision on a symbol (S), and to adjust at least one of the control parameters (ΔR, ρ, tᵢ) for subsequent decisions.

In order to improve the method, specifically, to enable the components of the control loop to provide a decision-based symbol more quickly without long delays, it is proposed that a preliminary, specifically an estimated, correction angle for an instantaneous rotation be supplied as a control parameter (ρ) to the decision element (15′, 15*) independently of a control for a local oscillator.

### PRIORITY INFORMATION

This application claims priority from DE 103 47 259.2 filed Oct. 8, 2003.

### BACKGROUND OF THE INVENTION

The invention relates to synchronizing a circuit during reception of a modulated signal that has been mixed in the multidimensional complex signal space.

In a conventional receiver designed to receive digital signals that have undergone two-dimensional modulation by a quadrature-amplitude-modulation (QAM) or a phase shift keying (PSK) method, a complex multiplier or mixer, driven by a local oscillator, mixes in a correct frequency and phase relation the received signal, which has been modulated on a carrier, into the baseband of the circuit. A phase-locked loop (PLL) ensures the correct frequency and phase of the local oscillator for mixing. In the case of digital processing, mixing may occur either before or after an analog-to-digital conversion. The signal is either sampled and digitized at the symbol clock rate or a multiple thereof, or the digitization clock rate is left free-running relative to the required symbol clock rate. In this case the signal is converted to the symbol clock rate or a multiple thereof through a purely digital sampling rate conversion. Gain controls ensure that the specific modulation range is utilized and that the received signals are correctly mapped to the symbol decision element stage. An adaptive equalizer prevents any inter-symbol interference originating in distortions of the transmitter, transmission path, or receiver.

In many demodulators for QAM signals or PSK signals, in order to achieve frequency and phase control the control circuits need both the received signals and those elements of the predetermined symbol alphabet viewed as the most probable by the decision element stage for the purpose of gain control, for recovering the symbol clock rate, and/or for the adaptive equalizer. These types of control using differences between the received and decision-based symbol current are called decision-feedback controls. Their use presupposes essentially correct decisions.

The conventional approach has been to use a decision that in the complex I/Q plane assigns the received signals to target symbols based on the least distance. If the target symbols are located on a uniform grid or matrix, a grid or box pattern for decisions is produced.

Since the decision-feedback controls are interlinked in prior art demodulators, locking is difficult as long as the control for the carrier of the local oscillator that mixes the received signal into the baseband is not yet stable in terms of frequency and phase, and faulty decisions occur as a result. Often locking is successful only when the frequency and phase are located relatively close to their target values.

If the carrier phase, particularly in the case of higher-order modulation procedures, is only a few degrees distant from the target phase, the symbols are often decided incorrectly. With 256 QAM, a deviation of only approximately 3 degrees is sufficient for faulty decisions to be made.

The difference in the phase of the received signal and the phase of the decision-based symbol is employed as the control voltage for carrier control.

FIG. 11 shows the time-averaged control voltage as a function of the deviation of the phase position of the received signal relative to the phase position of the local oscillator. It is readily evident that correct individual decisions, which lead to the rising lines, are made only in the central region. Outside of the central region, it is assumed that there are faulty individual decisions which, however, when averaged over time nevertheless lead at least to the correct sign.

FIG. 12 shows this control voltage on a different scale together with a line that would correspond to an ideal control voltage. This ideal control voltage is proportional to the phase deviation over the entire range.

EP 0571788 A2 discloses a carrier and phase control in which only the inner four symbols of the I/Q plane with an additional hysteresis are used in connection with a reduced constellation. However, in higher-order modulation methods having a uniform symbol distribution, the frequency of these symbols is only a very small component (e.g., only about 1.6% for uniformly distributed 256 QAM).

U.S. Pat. No. 5,471,508 discloses an operational mode of tracking by which the control operates using a reduced symbol alphabet in the I/Q plane wherein only large radii are taken into account.

DE 199 28 206 A1 discloses a method in which the complex I/Q plane is divided into smaller squares, thereby allowing an essentially unique average control voltage to be obtained. However, this method requires the use of large tables, and still does not solve the fundamental problem.

In a method disclosed in DE 41 00 099 C1, only the corners of the I/Q symbol alphabet are utilized, and again many symbols are lost as a result.

EP 0249045 B1 (U.S. Pat. No. 4,811,363, DE 36 19 744 A1) proposes a method in which a two-step decision is implemented. In a first step, a target radius is decided on then, in a second step, the most probable target phase point is assumed on this decision-based target radius. For 16-QAM constellations, such a method works to an acceptable degree. When a 64-QAM plane is used, however, 9 radii must be taken into account, some of which are very closely adjacent to each other. With 64 QAM, the radii boundaries and phase boundaries for a symbol are already located so closely together that effective radii decisions are almost impossible to obtain, especially in the event of additive noise. In the case of 256 QAM, the radii are so close together that very few radii decisions can be obtained at a sufficiently useful level.

The problem of correctly determining the phase deviation would not exist if the maximum phase deviation at each point in time were as large as the central region of FIG. 11 in which the phase deviations are always measured correctly. For stability reasons, it is almost impossible to have a quickly locking control that when given a frequency offset immediately detects and tracks the first passing correct phase position. That is particularly true considering the fact that practical implementations of the circuit have delays of multiple symbol clock pulses between the frequency/phase correction of the PLL-controlled oscillator with complex mixing of the input signal into the baseband and the symbol decision element. In addition, control filters are also located in the loop, and together cause significant signal delays that produce instabilities in the event of high loop gain.

Therefore, there is a need for an improved method and circuit for generating a symbol during reception of a modulated signal, specifically, for generating control signals, and to provide a receiving circuit which, in response to a large offset of the carrier frequency or carrier phase, quickly locks in without thereby affecting the overall stability of the system.

### SUMMARY OF THE INVENTION

A basis of the invention is a method for synchronizing a circuit during reception of a modulated signal that is mixed into the multidimensional complex signal space, wherein the decision is made by a decision element by analyzing a received signal within a complex coordinate space using control parameters and, depending on at least one decision-based symbol, the control parameters are adjusted for subsequent decisions. The demodulation here preferably takes place within a two-dimensional complex phase space, that is, in the baseband with the complex I and Q components. The method is also applicable to a one-dimensional signal, for example, a BPSK signal with points on the real axis when a merging or transformation into the multidimensional complex signal space or phase space is implemented for processing.

The especially preferred solution includes assigning a separate rotation device to the decision element, which device can perform an instantaneous rotation with a preliminary correction angle, specifically an estimated one, before the decision without taking into account the control of the local oscillator. The estimated correction angle is generated by an evaluation device coupled to the decision element. Analogous to this process is a procedure in which, instead of the signal, target symbols are rotated, or a combination of the two rotations is implemented. The preliminary or estimated rotation angle is checked by subsequent symbol decisions, then iteratively improved by integration of the aforementioned phase error until the actual rotation of the received signal relative to the reference coordinate system is recognized. In the case of a frequency offset, the rotation angle follows the increasing phase error. Control of this rotation, which depends on the phase error detected by the decision, may have an extremely high loop gain to ensure reliable locking into the phase position of the received signal. Since the control gain is limited to this circuit component, the stability of the actual carrier control, which may have a much lower loop gain, is not affected. Either the estimated rotation angle or a quantity derived therefrom is suitable as the input signal. In addition, the symbol decided upon can be advantageously supplied to the controls for gain, sampling time, and the equalizer. If the received signal has been rotated before the decision, the decision-based symbol must be back-rotated by the appropriate angle in these controls before use. This action enables this symbol, subsequently usually called the control symbol, to determine correction parameters for the aforementioned controls so as to enable the fastest possible synchronization of the circuit. The difference in the radii of the received signal and the decision-based symbol also enables gain control. The output data for additional processing steps can be obtained either from this decision element as well, or from a separate data decision element, the input data of which or the target symbols of which do not experience this additional rotation about the estimated value.

Accordingly, the rotation device and/or evaluation device preferably have a separate decision element that will be called an additional decision element or auxiliary decision element hereinafter. This additional decision element preferably has the function of a known decision element, although as an option a modified signal may be supplied to it.

Lacking a plausible estimate, the tilting action is effected in a first step by an angle of less than 360°, and preferably, taking into account the modulo of the quadrants, less than 90°.

Preferably, a tap of the signal components, especially the phase signal components, before and after the decision element may be used to determine a difference which indicates a deviation value that can be compared with the previously determined tilting angle. A filter device implements a plausibility check wherein diverse control parameters are used to specify as needed a wider or less wide tolerance range within which an adequate signal quality is detected so as to enable the circuit to lock in.

The decision element can preferably be operated both in the domain of the polar coordinate space and in the domain of the Cartesian coordinate space.

Preferably, a control device for the carrier frequency and carrier phase has a direct branch for controlling a phase deviation, and an integrator for controlling a frequency deviation, wherein for purposes of frequency control the integrator is supplied with the time derivative of the preliminary or estimated rotation angle, or with a signal formed therefrom. For purposes of phase control, a direct branch and the integrator are supplied with the estimated rotation angle or a signal formed therefrom.

Accordingly, a method has been developed in which the instantaneous rotation of the received coordinate system relative to the coordinate system of the circuit is estimated in the decision element itself and is tracked from symbol to symbol. The loop gain of the main control can still be very small. Occasional faulty decisions by assuming the incorrect tilt angle of the received signal have essentially no effect on the actual frequency and phase control since the real phase position is quickly detected again and locked in.

One specific application provided by the method, or the corresponding circuit, is in binary or complex digital modulation methods such as phase shift keying (PSK) and QAM. Modulation methods of this type are employed in current radio, television, and data operations using cable, satellite, and sometimes terrestrial means.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 illustrates a basic circuit for a decoder used to decide on a symbol;

FIGS. 2A-2c illustrate the position of a signal received in a tilted or rotated receiving coordinate system, and a fundamental principle for adjusting the coordinate system of the circuit by rotating a received signal and by oppositely rotating a decision-based auxiliary symbol;

FIGS. 3A-3B schematically illustrate the position of a signal received in a rotated receiving coordinate system, and the adjustment of a decision grid of the circuit by rotation;

FIG. 4 illustrates a section of a circuit to show an embodiment of a decision element in which the symbols and decision limits are rotated;

FIG. 5 illustrates a general embodiment of a decision element in which signals and symbols are rotated;

FIG. 6 shows details of the rotation control device controlling the process sequences that specifically affect the generation of a rotation control signal and amplitude error signal;

FIG. 7 illustrates another embodiment using a decision element in which rotation and counter-rotation, as well as the decision for a symbol, occur in a polar coordinate space;

FIG. 8 illustrates an embodiment of a carrier frequency device and phase control device;

FIGS. 9A, 9B illustrate an example of a measured phase error with 64 QAM (FIG. 9A) and the derivative of this signal, that is, the determination of a frequency offset, (FIG. 9B), while

FIGS. 10A-10C, for purposes of comparison, illustrate an example of the measured phase error with 64 QAM for the described method (FIG. 10A) and the derivation of this signal, that is, a determination of the frequency offset, for an open (FIG. 10B) or a closed (10C) control loop;

FIG. 11 illustrates averaged control voltages as a function of an angular deviation of −45° to +45° according to the prior art using a modulation according to 256 QAM; and

FIG. 12 is a diagram, as is FIG. 13, on a different scale, illustrating the ideal, theoretical control voltage function.

### DETAILED DESCRIPTION OF THE INVENTION

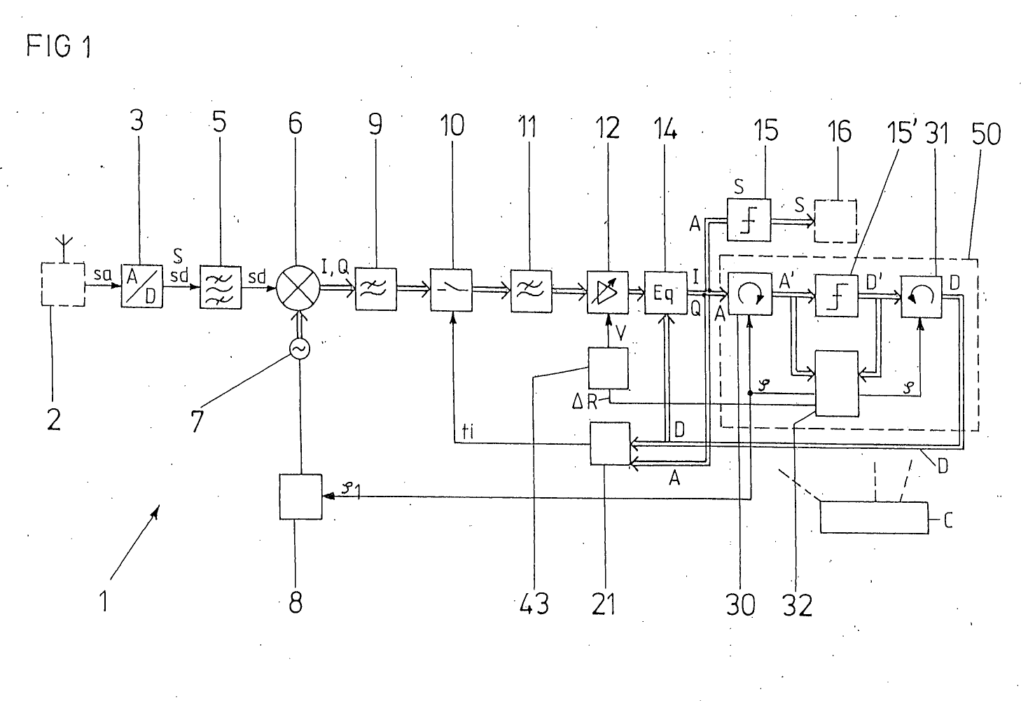

FIG. 1 illustrates a demodulator 1 that includes a plurality of individual components and represents one example of a circuit for determining and deciding on symbols S from a digitized signal sd that is coupled to a quadrature signal pair of a modulation method, for example, using the a QAM standard. These components may all or individually also be part of an integrated circuit. In particular, the components described below may be omitted or augmented by additional components, depending on the purpose of the application. In addition, the continuation of signals in the form of real signals, complex signals, or individual complex signal components may be appropriately adapted, depending on the purpose of the application and the specific circuit.

The demodulator 1 receives an analog signal sa from a signal source 2, for example, a tuner. This analog signal sa, which is usually present in a bandwidth-limited intermediate frequency position, is supplied to an analog-to-digital converter (ADC) 3 for conversion to a digital signal sd. The digital signal sd is supplied by the ADC 3 to a bandpass filter 5 that removes steady components and disturbing harmonics from the digital signal.

The signal outputted by the bandpass filter 5 is supplied to a quadrature converter 6 that converts digital or digitized signal sd to the baseband. The baseband matches the requirements of the demodulator 1 and the modulation method used. In analogous fashion, the quadrature converter outputs digitized signal sd that has been split up into the two quadrature signal components I, Q of the Cartesian coordinate system. To implement frequency conversion, the quadrature converter 6 is usually supplied with two carriers offset by 90° from a local oscillator 7, the frequency and phase of which is controlled by a carrier control device 8.

Quadrature signal components I, Q are outputted by quadrature converter 6 and supplied to a circuit for sampling conversion composed of a low-pass filter 9 and a symbol sampling device 10. Control of the symbol sampling device 10 is effected through an input to which a sampling signal tᵢ is supplied from a clock control device 21. In the normal operational state, the symbol sampling times for sampling signal tᵢ are governed by the symbol rate 1/T of the modulation method employed, or by an integral multiple thereof, and by the exact phase position of the received digital symbols. The output signal from the sampling device 10 is filtered by a low-pass filter 11 using a Nyquist characteristic, then supplied to a gain control device 12. The gain control device 12 serves to optimally cover the control range of a data or symbol decision element 15. The output signal from the gain control device 12 is supplied to an equalizer 14. The equalizer 14 removes interfering distortions from the two components of the quadrature signal pair I, Q and supplies a corrected signal I, Q or A at its output.

The complex received signal A available after the equalizer 14 is thus supplied in the conventional manner to the data decision element 15 that extracts the digital data S. These symbols S are then supplied to another digital signal processing device 16. This decision element 15 is not, however, integrated into the decision feedback controls of carrier frequency/carrier phase (carrier/phase recovery), sampling time (timing recovery, clock recovery), gain control, or equalizer. Instead, these control branches are controlled by a special auxiliary circuit 50 with an additional decision element—also called control decision element 15′ for purposes of differentiation—which has a modified input signal A′ supplied to it.

To this end, signal A outputted by the equalizer 14 is supplied to a system of components 30-32 to determine control parameters (D, D′, ΔR, ρ), either some or all of which may also be implemented integrally within a signal semiconductor module as hardware, software, or in mixed form. These control parameters are then supplied directly or indirectly to the decision-feedback control circuit or components in the demodulator 1. Specifically, the equalizer 14, the gain control device 12, the carrier control device 8, and a control device, particularly a clock control device 21 for the symbol sampling device 10, are supplied in this way with auxiliary symbols D′ from the decision element 15′, or with control symbols D, or symbol components R, α, or other signals ΔR, ρ generated therefrom.

Depending on the circuit, these control circuits are supplied with the two quadrature signal components of the symbol D or D′, and of signal A or A′ in Cartesian coordinates I, Q, or in polar coordinates R, α. Depending on the circuit, another possible technique is to supply individual components with only one of the quadrature signal components, or quantities derived therefrom, for example to supply the carrier control device 8 with a value ρ derived from the angle α of the preliminary symbol A and the angle of control symbol D, and the gain control device 12 with the difference ΔR of the radii of the signal A, A′ and of symbol D, D′.

In FIG. 1, a special circuit 50 for determining the control parameters is composed of a rotation device 30, a control decision element 15′, an additional rotation device 31, and a rotation control device 32.

The rotation device 30 rotates signal A outputted by the equalizer 14 about a predetermined quantity ρ and supplies the resulting complex signal A′ to control the decision element 15′ that generates an auxiliary symbol D′. To implement the rotation, a rotation control signal ρ is supplied to the rotation device 30. Rotation control signal ρ matches an estimated instantaneous rotation angle or tilting angle ρ between the coordinate system of received signal sa, sd, and the coordinate system of the circuit 1. Rotation control signal ρ is determined within the rotation control device 32 to which output signal A′ of the rotation device 30 and output signal D′ of the control decision element 15′ are supplied.

Output signal D′ of the control decision element 15′ is also supplied to the counter-rotation device 31 to implement an opposite rotation. Rotation control signal ρ from the rotation control device 32 is supplied to the counter-rotation device 31 in order to back-rotate auxiliary symbol D′ decided upon within the system of the circuit into the coordinate system of the received signal. The output signal D from the counter-rotation device 31 is used for the control circuits and, for example, supplied to clock control device 21 and the equalizer 14. The two rotation devices 30, 31, generate unitary rotations and are formed, for example, using known complex multiplications with sine and cosine.

Rotation control device ρ is appropriately generated by the rotation control device 32 from the angles of signal sequence A′ and the angles of auxiliary signals D′.

The clock control device 21 outputs sampling signal tᵢ which is based on the symbol rate 1/T of the modulation method employed, or a multiple thereof.

To implement control of the clock control device 21, the carrier control device 8, the equalizer 14, the rotation control device 32, the control device 43 for the gain control device 12, and the additional components of the demodulator 1, these components are connected to control device C. Control device C implements the proper sequence and controls the individual components and sequences of corresponding hardware- and software-based instructions. Preferably, the control device may also have the functions of some or all of the above components integrated within it.

The specific purpose of the circuit is to generate a control voltage or control voltage function, utilizing modulo-90′, as shown in FIG. 12.

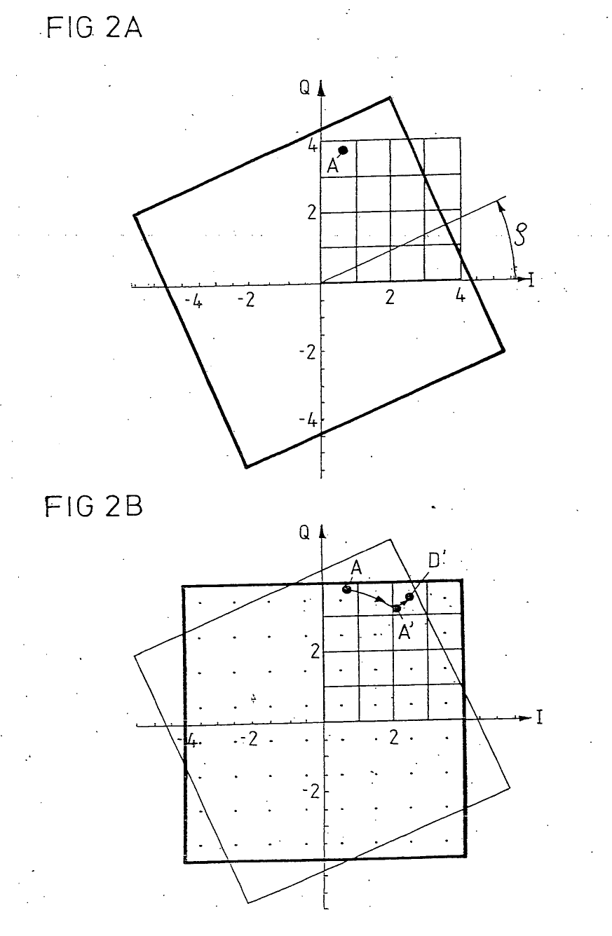

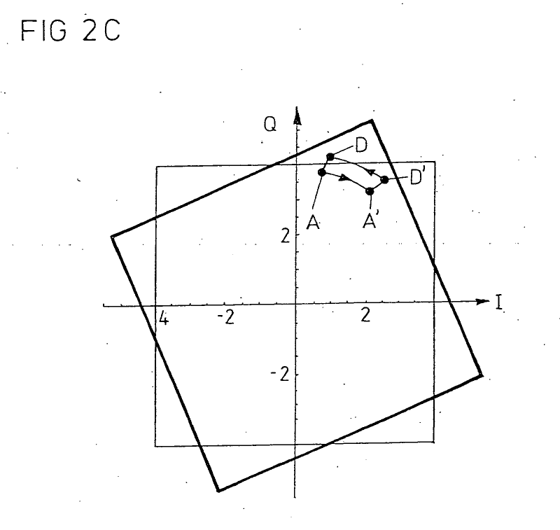

It is assumed that at a first time t1 at which the phase and frequency of the receiver have not yet locked in, the coordinate system of input signal A is still tilted by angle ρ relative to the reference coordinate system, and may even have to be rotated due to a frequency offset, as shown in FIG. 2A. Accordingly, a received signal is not immediately decided upon in the indicated grid of the circuit 1 since a rotation of the received coordinate system about angle ρ is assumed.

Input signal A outputted by the equalizer 14 is now rotated within the rotation device 30 by this tilting angle ρ into the circuit system so that in a first approximation a phase error is no longer present. After the rotation shown in FIG. 2B into the circuit system, this rotated signal A′ is then supplied to an auxiliary decision element 15′ that makes a decision within the fixed circuit system. Here rotated input signal A′ is assigned in the conventional manner to a target symbol. The counter-rotation device 31 rotates decision-based symbol D′ in the opposite direction by angle ρ from the coordinate system of the circuit 1 back into the presumed coordinate system of the received signal. After this opposite rotation, input signal A has a decision-based control symbol D, although the actual carrier control device—composed specifically of the carrier control device 8, the local oscillator 7, and the quadrature converter 6—has not yet locked in. A target point and a complex error voltage are thus available, as is shown in FIG. 2C.

Input signal A into circuit 50 and control symbol D generated therein can be employed for the decision-feedback controls of the sampling time recovery and of the equalizer 14. The presumed rotation angle ρ of input signal A—determined from input signal A and symbol D, or A′ and D′—can be employed for the decision-feedback carrier control within the carrier control device 8; and similarly within the circuit 32 an amplitude deviation ΔR—derived from input signal A and symbol D, or A′ and D′, and obtained by subtracting the radius of auxiliary symbol D, D′ from the radius of input signal A, A′—can be employed for the purpose of decision-feedback amplitude control within the amplitude control device 43.

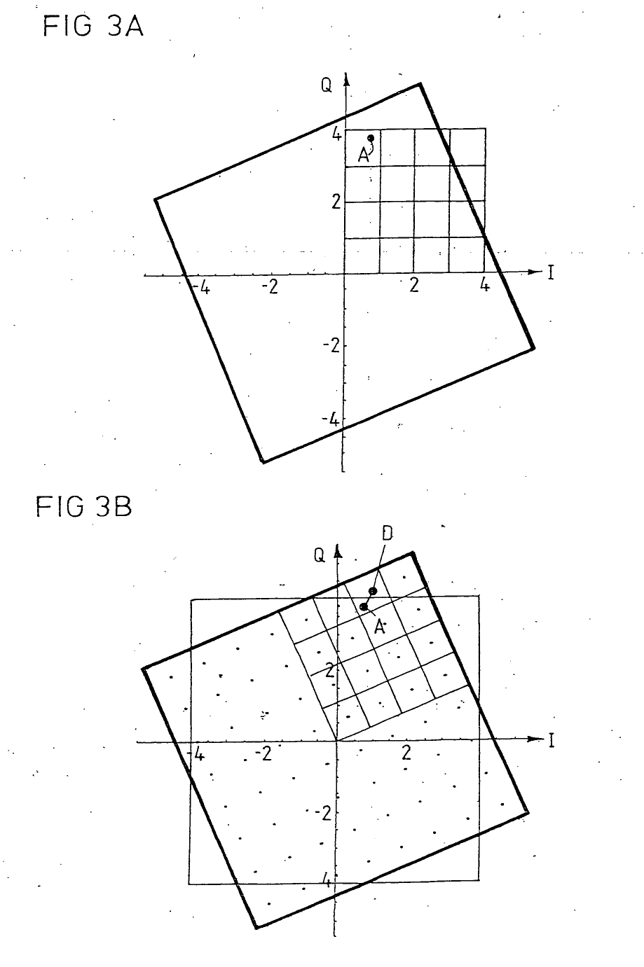

In an alternative approach to rotating the coordinates of the received signal into the system of the circuit and back-rotating the decision-based symbol into the coordinate system of the received signal as the control symbol for the purpose of decision-feedback controls, it is also possible, as shown in FIG. 3B, to rotate the decision grid relative to the original (FIG. 3A) so that its coordinate system matches the coordinate system of received signal A.

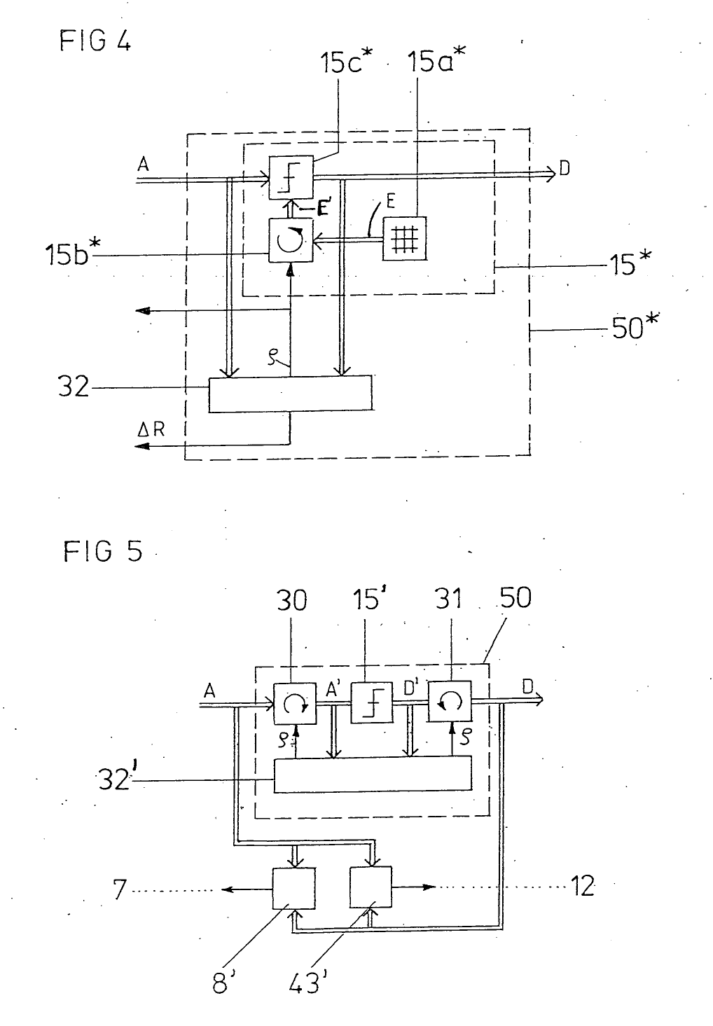

FIG. 4 illustrates a section of such a circuit 1 wherein the specific rotation 50* corresponds to the block 50 shown in FIG. 1 with the rotation, decision element, and control components. In regard to additional components, reference is thus made to FIG. 1 and the associated description. To implement the above-outlined method, circuit 50* shown employs decision limits E which are provided, for example, from a table in memory 15a*. In a computing unit 15b* acting as the rotation unit, the decision limits E′ are rotated so that the estimated rotation of the received signal sa, sd, A is achieved relative to the coordinate system of the circuit. These thus rotated decision limits E′ are supplied to the decision element 15c*. The decision then occurs directly in the estimated coordinate system of received signal A without the prior rotation of the received signal and subsequent opposite rotation of the symbol generated thereby.

In this and other embodiments, methodological steps and components already described with reference to the above descriptions for the same or analogously functioning methodological steps and components are not repeated.

Specifically, the two methods—rotation of the received signal and counter-rotation or back-rotation of the decision-based symbol, or rotation of the decision limits—are equivalent and interchangeable. One of these two methods is preferably implementable depending on the given technical means of implementation. The following discussion explains additional details specifically of the first embodiment, although equivalent implementations are also possible for the second embodiment.

FIG. 5 illustrates a more general embodiment of the circuit block of the circuit 50. In this block, the preliminary symbol A is supplied to the rotation device 30 that outputs a rotated symbol A′ after rotation. This symbol is supplied both to the decision element 15′ and to the rotation control device 32′. The decision-based auxiliary symbol D′ outputted from the control decision element 15′ is supplied both to the counter-rotation device 31 and the rotation control device 32′. The rotation control device 32′ generates a control signal ρ for the rotation device 30 and the counter-rotation device 31 which is supplied to these devices. In addition, original symbol A of the equalizer 14 is supplied directly to the carrier control device 8′ and the amplitude control device 43′. These devices additionally have supplied to them control symbol D which is outputted by the counter-rotation device 31. This control symbol D is appropriately also supplied to the clock control device 21 and the equalizer 14. In addition, the clock control device 21 has supplied to it symbol A outputted by the equalizer 14.

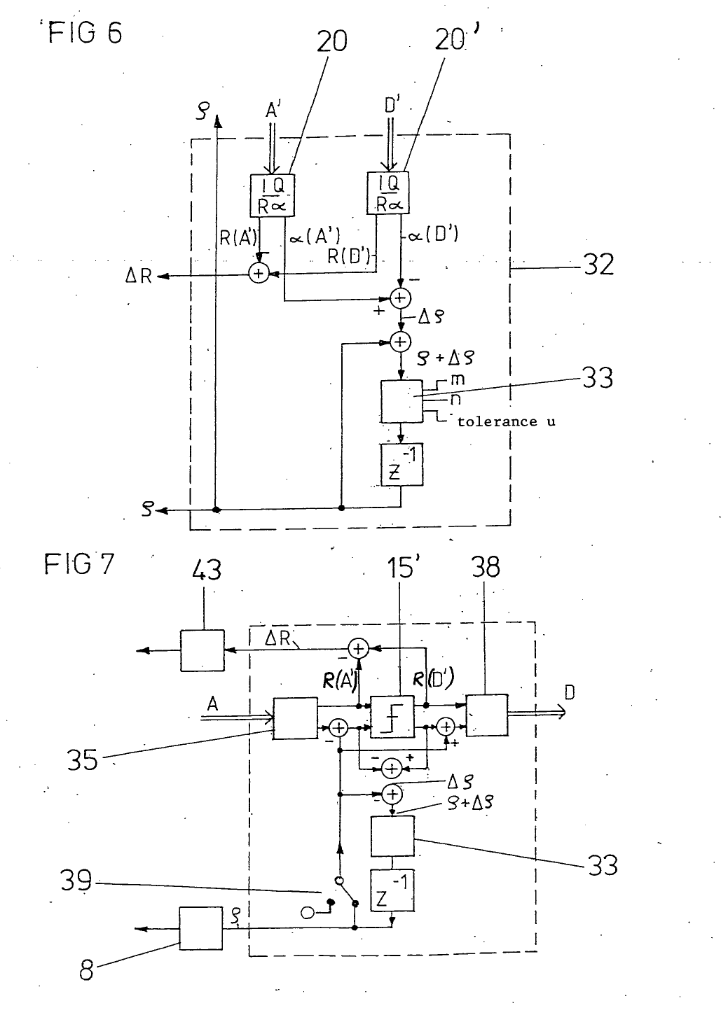

An example of the rotation control device 32 is illustrated in FIG. 6. The rotated symbol A′ as the input signal and the decision-based auxiliary symbol D′ outputted by the decision element 15′ are supplied to the rotation control device 32. These two signals or symbols A′, D′ are each supplied to one coordinate converter 20 or 20′ which convert these to polar coordinates. An example of what can be used here is a known Cordic circuit. Each of these outputs a radius component R and an angle component or phase α. Alternative methods of coordinate conversion are usable, specifically, mathematical approximation techniques or the use of tables. The amplitude difference ΔR is determined by subtracting the radius components R(A′), R(D′), which difference is outputted as the control signal for the amplitude control device 43. The phase or angular difference Δρ is determined by corresponding subtraction of the phase of symbol D′ outputted by decision element 15′ from the phase of input signal A′ and represents the phase estimation error. This phase difference Δρ is supplied to a circuit composed of an adder, a filter device 33, and a delay element (z⁻¹), whereby the output signal ρ of this arrangement sequence is returned to the second input of the adder. The sum generated from the phase component ρ and the phase difference Δρ represents the most probable current coordinate rotation angle ρ+Δρ found of the signal entered into the decision element 15′ relative to the system of the circuit. This sum ρ+Δρ is checked in filter 33 for plausibility. The output from filter 33 simultaneously provides the rotation angle ρ for the next decision to be made. Rotation angle ρ is supplied specifically to the rotation device 30, the counter-rotation device 31, and the carrier control device 8.

The embodiments described above represent examples of a preferred QAM receiver or decoder with decision-making of the control or auxiliary decision-making in the Cartesian coordinate system I/Q.

FIG. 7 represents an embodiment in which the decision-making is implemented in the decision element 15′ within the polar coordinate system. Rotation and counter-rotation are effected by prior conversion of the signal to polar coordinates and simple subtraction or addition of the rotation control signal or tilting angle from or to the phase component. In addition, the decision-making also occurs within the polar coordinate system.

This embodiment advantageously also has an optional switch 39 by means of which the integration of the phase difference can be preserved after synchronization of the carrier control circuit has occurred.

To generate the next rotation control signal ρ, the phases of the input signal and output signal A′ or D′ are tapped before or after the decision element 15′, then supplied to a subtraction element. This element determines the phase difference Δρ which is supplied to another addition element. This addition element adds the phase difference and the current rotation control angle ρ. The sum is then supplied to the filter device 33.

The switch 39 here is connected within the return branch of the prior adder, filter device 33, and delay element (z⁻¹). In the nonconducting position of the switch 39, the rotation angle ρ determined is supplied as the rotation control signal only to the carrier control device 8.

Additional parameter values m, n, and a tolerance value u are supplied to the filter device 33. These may, for example, be supplied from a memory device or from an external central control device.

After delay element z⁻¹, the output signal from the filter 33 is available as the new rotation control signal ρ for the next decision at the next time point. The filter device within this rotation control checks the found current rotation angle ρ+Δρ for plausibility and adjusts rotation control signal ρ for the next time point.

The filter device 33 outputs an arbitrary value for rotation control signal ρ. An offset Δρ thereby determined can then be attributed to a still insufficient estimation of rotation control signal ρ. In the event of an extremely insufficient estimation of rotation control signal ρ at the start, many decisions will be incorrect due to incorrect symbol assignment within the decision element 15′. There are angle offsets, however, for which most or even all decisions are correct, that is, rotation control signal ρ has been correctly estimated and angular difference Δρ is approximately 0°. If the input signal A rotates due to a frequency offset—a condition that can be assumed in the case of carrier control loops that have not locked in—then sooner or later the system will pass through one such “good” angle offset region. All or many of the found successive rotation angles ρ+Δρ will have identical or similar values. The filter device 33 now recognizes that at least m of n, for example, 4 of 8, of the last found rotation angles ρ+Δρ match the present rotation control signal ρ up to a tolerance u, for example, 0.1 rad, and considers the present found rotation angle ρ+Δρ to be plausible so as to be able to use this as the next value for rotation control signal ρ. Parameters n, m, u, may be advantageously adapted to the reception conditions or the progress of synchronization.

The simplest implementation of the filter device 33 is an identity stage which corresponds to a short between input and output. The next rotation control signal ρ is then the currently found rotation angle ρ+Δρ.

If the actual phase control has locked in, rotation control signal ρ can be limited to the found angle deviation Δρ by causing the switch 39 shown in FIG. 7 to prevent the angle integration.

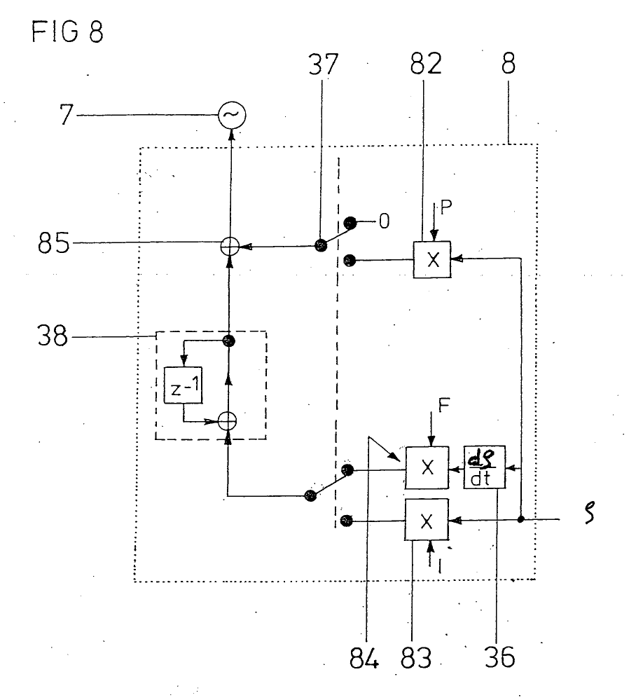

FIG. 8 shows details of the carrier control device 8. The carrier frequency and carrier phase control device 8 is preferably composed of a differentiator 36, three multiplication elements 82, 83, 84, a double-pole two-way switch 37, an integration element 38, and an adder 85.

The tilting angle or rotation control signal ρ is supplied as the first quantity to the two multiplication elements 82, 83, and a P-coefficient or an I-coefficient is supplied to these elements as the second quantity. In addition, rotation control signal ρ is supplied to a differentiator 36 (dρ/dt), the output signal of which is supplied to another, third multiplication element 84. An F-coefficient for frequency control is supplied as a second signal to this element. A double-pole switch 37, on the one hand, switches the output of I-multiplier 83 or the output of F-multiplier 84 to integrator 38, the output of which is supplied to adder 85. On the other hand, double-pole switch 37 switches between the output of P-multiplier 82 and an unassigned input, the output signal of the switch also being supplied to adder 85. The output of adder 85 supplies an error signal to local oscillator 7.

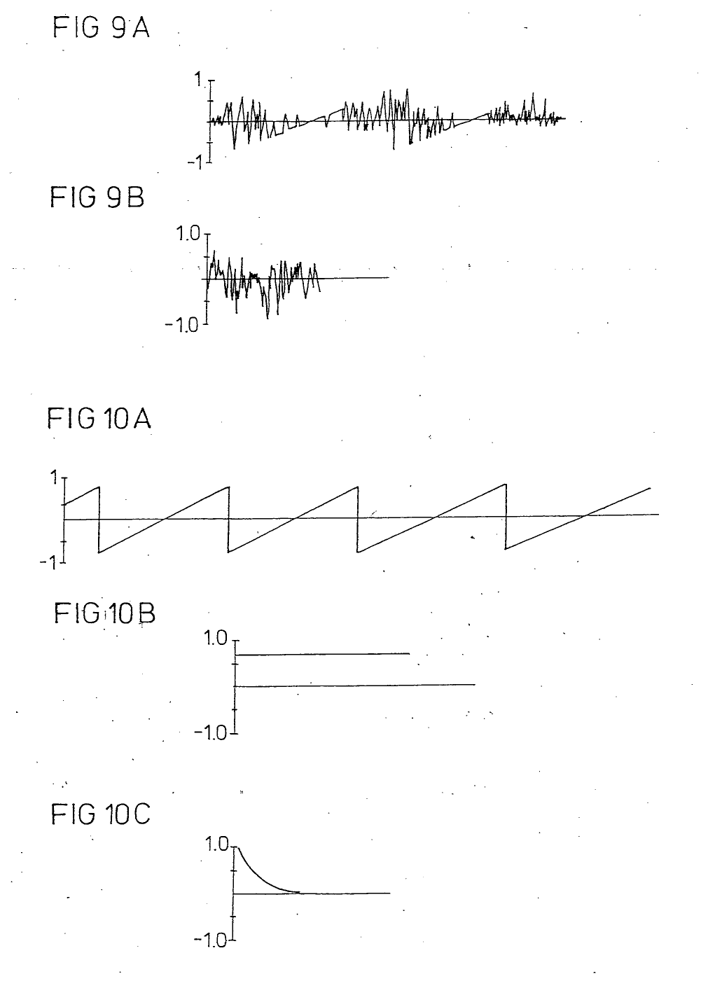

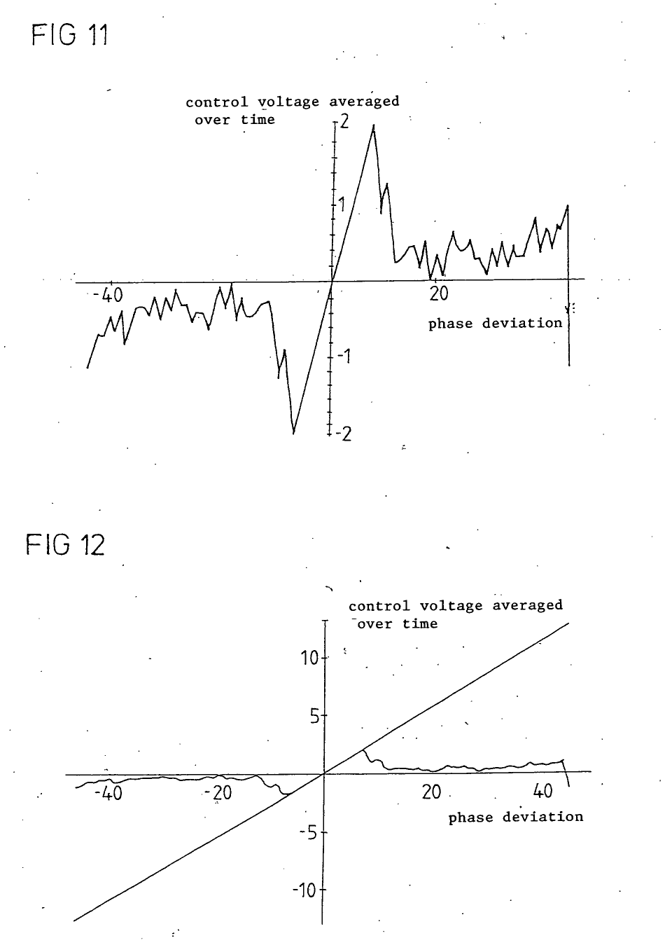

At the start of the synchronization process, the switch 37 is in the position in which the upper switching element supplies a zero signal, while the lower switching element supplies the signal mixed with coefficient F. As a result, the modulo-correct derivative of rotation control signal dρ/dt, which represents a possible frequency offset Δf, is weighted with the F-coefficient and accumulated in integrator 38. Once the oscillator 7 finally has approximately reached the target frequency due to the control voltage coming from the integrator 38, dρ/dt will become very small. Under this condition, dρ/dt≈0, the switch 37 is moved to the other switching position by the central control device C of the circuit 1, thus obtaining the usual PI control (proportional/integral control) of the phase. The integral component in the integrator 38 obtained through the prior frequency control remains intact. A principal advantage consists is the fact that coefficients F, P and I in the carrier control device 8, and thus the loop gain of the main control for carrier frequency and carrier phase, can be very small since fast phase tracking occurs in the circuit 50 and is limited to the circuit 50.

Whereas a control voltage, such as that illustrated in FIG. 12, would ideally run from a normalized value −1 at −45° in a straight line through the origin to a normalized value of +1, this is not the case with actual phase control voltages. FIG. 9A illustrates a conventional phase control voltage for 64 QAM as a function of time. Regions are clearly evident in which the phase offset repeatedly passes through zero such that a control may lock in whenever its gain is able to be large enough. In connection with this example of an open control loop, FIG. 9B shows the frequency control voltage obtained from a derivative of the signal on a time axis which is compressed relative to FIG. 9A. In this example, the frequency offset is approximately 2,000 ppm of the symbol rate.

A corresponding curve of a phase control voltage with a measured rotation control signal ρ using 64 QAM in accordance with the method here proposed is presented in FIG. 10A. What is significant is not only the segment-wise almost linear pattern similar to that of FIG. 12, but also the fact that, after individual outliers, filter 33 or circuit 1 are able to very quickly recapture the correct phase. In this example, the frequency offset is again approximately 2,000 ppm of the symbol rate, while the signal/noise ratio is the same as in FIG. 9. In this example with an open control loop, FIG. 10B illustrates the measured frequency offset dρ/dt for the signal, but on a compressed time axis. FIG. 10C shows the corresponding frequency offset dρ/dt for the case with a closed control loop. The scale for FIGS. 10B and 10C is matched to that of FIG. 9B.

The method and circuit 1 preferably function to synchronize a QAM receiver. In circuit 1, there is a circuit 50 in which a found angular difference between received signal A′ and decision-based symbol D′ is integrated and checked for plausibility. This angular difference Δρ, integrated and checked in the rotation control device 32, serves as rotation control signal ρ. As a result, subsequently received signals A are rotated immediately before decision element 15′ and thus corrected. Alternatively, the coordinate system of the decision element can be rotated by the opposite angle. The actual control signal for the local oscillator 7 is thus formed from this rotation control signal ρ in a control circuit 8. The carrier control locks in even in the event of a very small loop gain. The decision-based symbol D′, or possibly the back-rotated symbol D or its difference relative to input signal A, A′ can continue to be employed for the sampling rate 21, the gain 43, and the equalizer 14. The subsequent processing steps contain either the symbol D thus decided upon, or a symbol S from an additional decision stage 15 that does not participate in the described rotations of the circuit 50.

Although the present invention has been shown and described with respect to several preferred embodiments thereof, various changes, omissions and additions to the form and detail thereof, may be made therein, without departing from the spirit and scope of the invention.

1. Method for synchronizing a circuit (1) during reception of a modulated signal (sa, sd) that has been mixed into the multidimensional complex signal space, wherein
a decision element (15′; 15*) is employed to analyze a received signal (sa, sd, A) within a complex coordinate space (I, Q) using control parameters (ΔR, ρ, tᵢ) so as to make a decision, specifically, to decide on a symbol (D′, D) and to adjust at least one of the control parameters (ΔR, ρ, tᵢ) for subsequent decisions, characterized in that
a preliminary, specifically, estimated correction angle for an instantaneous rotation is supplied as the control parameter (ρ) to the decision element (15′; 15*) independently of a control for a local oscillator.

2. Method according to claim 1, wherein
a decision element or additional decision element (15′; 15c*) is employed to decide on a parameter and/or a symbol (D′) which is used to adjust the control parameters (ΔR, ρ, tᵢ), and
to this end, the received signal (A) is preprocessed to pre-rotate the received signal (A) by adjusting or changing the correction angle (ρ) before it is supplied to the decision element (15′), and/or
to this end, a circuit-internal decision grid (E) is preprocessed by rotating and supplying said grid to the decision element (15c*), and supplying the received signal (A) to this element.

3. Method according to claim 1, wherein a value comparison of at least signal components before and after the decision element (15′; 15c*) is implemented to determine a deviation value of the angle (ρ) and/or of the amplitude (ΔR) between the received signal (A, A′) and the system of the circuit (1), which comparison is used for correction during subsequent steps.

4. Method according to claim 3, wherein a filter device (33) is used for processing to check the relationship relative to a previously used rotation (ρ) in connection with a determination of a correction angle and the resulting deviation value (Δρ+ρ).

5. Method according to claim 3, wherein an integrator utilizes a frequency offset (dρ/dt) for frequency control as long as an offset (dρ/dt≠0) of the carrier is detected.

6. Method according to claim 5, wherein a changeover from frequency control to phase control is implemented after the determination of a sufficiently precise frequency deviation with a determined tilting angle as the control parameter (ρ).

7. Method according to claim 1, wherein the processing within the decision element (15′; 15c*) is implemented within the polar coordinate space (R, α).

8. Method according to claim 1, wherein
in a first step, as the correction angle an arbitrary or specified tilting angle (ρ) is used as a predetermined control parameter to achieve pre-rotation for a first estimation;
the estimation of an additional tilting angle (ρ) is implemented by correcting the last estimation using a predetermined angle error (Δρ) of an additional received signal (A) determined by the decision element (15′; 15c*); and
a filtering and a plausibility check of the previous correction is implemented to determine the new correction angle (ρ).

9. Method according to claim 1, wherein the symbol (D′) is moved into the coordinate system of the received signal (A) for further processing by back-rotation about the tilting angle (ρ).

10. Method according to claim 1, wherein the symbol (D′) or a signal derived therefrom (ρ) is used for further processing as the input signal for the purpose of carrier frequency control or carrier phase control (8).

11. Method according to claim 1, wherein an angle difference between the received signal (A) and the back-rotated symbol (D), or a signal derived therefrom, is used as the input signal for a carrier frequency or carrier phase control (8).

12. Method according to claim 1, wherein the symbol (D; D′), or a signal derived therefrom is used as the input signal for a control device (21) to adjust a sampling rate frequency and/or phase.

13. Method according to claim 1, wherein the symbol or a signal derived therefrom (D; D′) is used as the input signal for a control device (43) of an equalizer (14).

14. Method according to claim 1, wherein a signal derived from the symbol, specifically, a radius component (ΔR), is supplied to a control device (43) for a decision-feedback gain control device (12).

15. A circuit (1) including a circuit (50; 50*) to synchronize the circuit (1) during reception of a modulated signal (sa, sd) that is mixed into the multidimensional complex signal space, comprising:
a decision element (15′; 15*) to analyze a received signal (sa, sd, A) within the complex coordinate space (I, Q) using control parameters (R, ρ, tᵢ), and
at least one control device (6, 7, 8, 9, 21, 10, 11, 43, 12, 14) to control a preprocessing of the received signal, characterized by
a preprocessing device (30, 32; 30, 32′; 35, 33, 36) to rotate the received signal (A) and/or to rotate a decision grid (E′) of the coordinate system of the circuit about a preliminary, specifically, estimated correction angle, independently of a control for a local oscillator (7).

16. Circuit (1) according to claim 15, comprising the decision element (15′; 15c*) to analyze the rotated received signal (A′) or received signal (A), including a pre-rotated decision grid (E′) and decision-making oh a symbol (D′, D) to determine at least one control parameter (ρ) for future decisions.

17. Circuit according to claim 16, wherein the decision element (15′; 15c*) is located outside the data path in which an additional decision element (15) is located to generate a symbol (S) to be outputted, whereby the two data paths have supplied to them a received signal (A) corrected using a method according to claims 1-14.

18. Circuit according to claim 15, wherein in order to control a deviation of the carrier frequency and phase a control device (8) has a differentiator to form the derivative, and an integrator, whereby the integrator (38) has an input to supply a control parameter (p) or derivative (dρ/dt, 36) thereof, or a signal (dρ/dt) formed therefrom.
